(19) United States
(12) Patent Application Publication
(10) Pub. No.: US 2026/0344083 A1
(43) Pub. Date: Oct. 29, 2026

(54) SOLID STATE IMAGING DEVICE

(71) Applicant: Samsung Electronics Co., Ltd., Suwon-si (KR)

(72) Inventors: Yoshito IWASA, Yokohama (JP); Kazufumi SHIOZAWA, Yokohama (JP); Yoshiharu KUDO, Yokohama (JP)

(21) Appl. No.: 19/652,168

(22) Filed: Apr. 20, 2026

(30) Foreign Application Priority Data
Apr. 25, 2025 (JP) 2025-072864

(51) Int. Cl. H10F 39/00; H10F 39/18

(52) U.S. Cl. CPC H10F 39/8067; H10F 39/18; H10F 39/8063; H10F 39/807; H10F 39/811

(57) ABSTRACT

A solid state imaging device can improve QE while suppressing the deterioration of dark. The solid state imaging device includes a pixel array in which a plurality of pixels are two-dimensionally arranged, the pixel has a photodiode having a first side upon which light is incident to the photodiode and a second side opposite the first side, a dielectric layer provided on the second side, and a light control region provided on the second side and disposed in the dielectric layer so that at least part of the dielectric layer is between the photodiode and the light control region. The light control region has a light diffraction grating in which a high-refractive-index layer and a low-refractive-index layer are periodically arranged.

### CROSS-REFERENCE TO RELATED APPLICATIONS

This U.S. non-provisional patent application claims priority under 35 U.S.C. §119 to Japanese Patent Application No. 2025-072864, filed on Apr. 25, 2025, in the Japanese Intellectual Property Office, the entire contents of which are hereby incorporated by reference.

### BACKGROUND

A solid state imaging device is mounted in various mobile terminals such as a digital camera and a mobile phone. In general, the solid state imaging device includes a photodiode arranged in a two-dimensional array, an on-chip lens provided on a side on which light is incident to the photodiode, and a wiring layer provided on a side opposite to the side on which the on-chip lens of the photodiode is provided. The photodiode may be arranged in a two-dimensional array of a plurality of units. Generally, a high quantum efficiency (QE) is required for the solid state imaging device. In this regard, for example, International Publication No. WO 2023/013461 forms a wiring layer side of the photodiode with a Shallow Trench Diffraction (STD) structure, thereby increasing an optical path length to improve QE.

The solid state imaging device of the International Publication No. WO 2023/013461 etches Si constituting a photodiode to form an STD. However, in this case, when Si is etched to form the STD, dark current characteristics may be deteriorated.

### SUMMARY

A solid state imaging device according to an embodiment may comprise: a pixel array in which a plurality of pixels are two-dimensionally arranged. Each of the pixels comprises: a photodiode a first side upon which light is incident to the photodiode and a second side opposite the first side; a dielectric layer provided on the second side; and a light control region provided on the second side and disposed in the dielectric layer so that at least part of the dielectric layer is between the photodiode and the light control region. The light control region may have a light diffraction grating in which a high-refractive-index layer and a low-refractive-index layer are periodically arranged.

The light diffraction grating may have a first side facing the photodiode and a second side facing away from the photodiode, and the light control region may have a light reflection region that is provided on the second side of the light diffraction grating and at a boundary between adjacent pixels and reflects the light.

The light diffraction grating may be provided adjacent to the dielectric layer.

Each of the pixels may further include a wiring layer provided on the one side of the photodiode, and the light control region may be formed between the photodiode and the wiring layer.

Each of the pixels may be a Single Photon Avalanche Diode (SPAD) pixel, and each of the pixels may further include an anode electrode and a cathode electrode, and when viewed in a plan view, the cathode electrode is provided in a center of the pixel, and the anode electrode may be provided at four corners of each of the pixels.

When at least one of the high-refractive-index layer or the low-refractive-index layer is formed of a conductive material, at least one of the anode electrode or the cathode electrode may be covered by an insulating layer.

The high-refractive-index layer may be provided to be one of an island shape, a ring shape, or a line shape.

A period of the light diffraction part may be set such that the light is totally reflected at the light reflection part.

A height of the light diffraction part may be smaller than a wavelength of the light.

The low-refractive-index layer may be one of a hollow structure or SiO.

The high-refractive-index layer may be one of polysilicon, TiO, or SiN.

According to some embodiments, a solid state imaging device includes a pixel array in which a plurality of pixels are two-dimensionally arranged. Each pixel of the plurality of pixels comprises: a microlens, a photodiode having a first surface facing the microlens and a second surface opposite the first surface, the photodiode configured to receive light from the microlens at the first surface, a dielectric layer below the photodiode; and a light control region in the dielectric layer. The light control region may include a diffraction grating that includes a matrix of first refractive-index material surrounded by a layer of a second refractive-index component, the first refractive-index material having a higher refractive index than the second refractive-index component.

According to some embodiments, a pixel array includes a plurality of pixels are two-dimensionally arranged. Each of the pixels may include a photodiode having a top side upon which light is incident to the photodiode and a bottom side opposite the top side, a dielectric layer provided on the bottom side, a light diffraction grating provided below the dielectric layer and configured to receive light having passed through the photodiode, the light diffraction grating including two patterns alternately arranged, and a reflection region below the light diffraction grating and configured to reflect refracted light that has passed through the diffraction grating back to the photodiode.

### BRIEF DESCRIPTION OF THE DRAWINGS

FIG. 1a is a plan view showing a pixel region composed of a plurality of pixels in a solid state imaging device according to an embodiment.

FIG. 1b is a front cross-sectional view showing part of a solid state imaging device according to an embodiment.

FIG. 2 is a front cross-sectional view showing a part of a pixel in a solid state imaging device according to an embodiment.

FIG. 3 is a plan view of the pixel in a solid state imaging device according to an embodiment.

FIG. 4 is a view corresponding to FIG. 3 of a pixel according to Modification 1.

FIG. 5 is a view corresponding to FIG. 3 of a pixel according to Modification 2.

FIG. 6 is a view corresponding to FIG. 3 of a pixel according to Modification 3.

FIG. 7 is a view corresponding to FIG. 3 of a pixel according to Modification 4.

FIG. 8 is a view corresponding to FIG. 3 of a pixel according to Modification 5.

FIG. 9 is a diagram for explaining an effect of a light control region of a solid state imaging device according to an embodiment.

FIG. 10 is a diagram for explaining a manufacturing method of a solid state imaging device according to an embodiment.

FIG. 11 is a diagram for explaining the manufacturing method of a solid state imaging device according to an embodiment, which continues from FIG. 10.

FIG. 12 is a diagram for explaining the manufacturing method of a solid state imaging device according to an embodiment, which continues from FIG. 11.

FIG. 13 is a diagram for explaining the manufacturing method of a solid state imaging device according to an embodiment, which continues from FIG. 12.

FIG. 14 is a diagram for explaining the manufacturing method of a solid state imaging device according to an embodiment, which continues from FIG. 13.

FIG. 15 is a diagram for explaining the manufacturing method of a solid state imaging device according to an embodiment, which continues from FIG. 14.

FIG. 16 is a diagram for explaining the manufacturing method of a solid state imaging device according to an embodiment, which continues from FIG. 15.

FIG. 17 is a diagram for explaining the manufacturing method of a solid state imaging device according to an embodiment, which continues from FIG. 16.

FIG. 18 is a diagram for explaining the manufacturing method of a solid state imaging device according to an embodiment, which continues from FIG. 17.

FIG. 19 is a diagram for explaining the manufacturing method of a solid state imaging device according to an embodiment, which continues from FIG. 18.

FIG. 20 is a diagram for explaining the manufacturing method of a solid state imaging device according to an embodiment, which continues from FIG. 19.

FIG. 21 is a diagram for explaining the manufacturing method of a solid state imaging device according to an embodiment, which continues from FIG. 20.

### DETAILED DESCRIPTION

In the drawings, the size and relative sizes of layers and regions may be exaggerated for clarity. Like numbers refer to like elements throughout.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that result from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact. As the state of contact is binary (either in contact or not in contact), it will be appreciated that “contact” has the same scope as any use of “direct contact.”

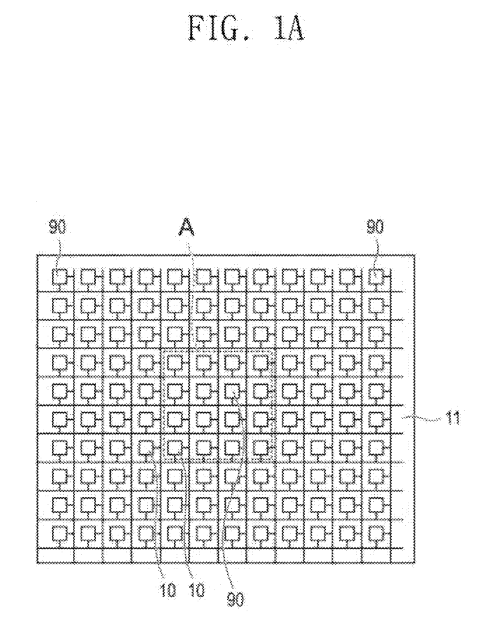

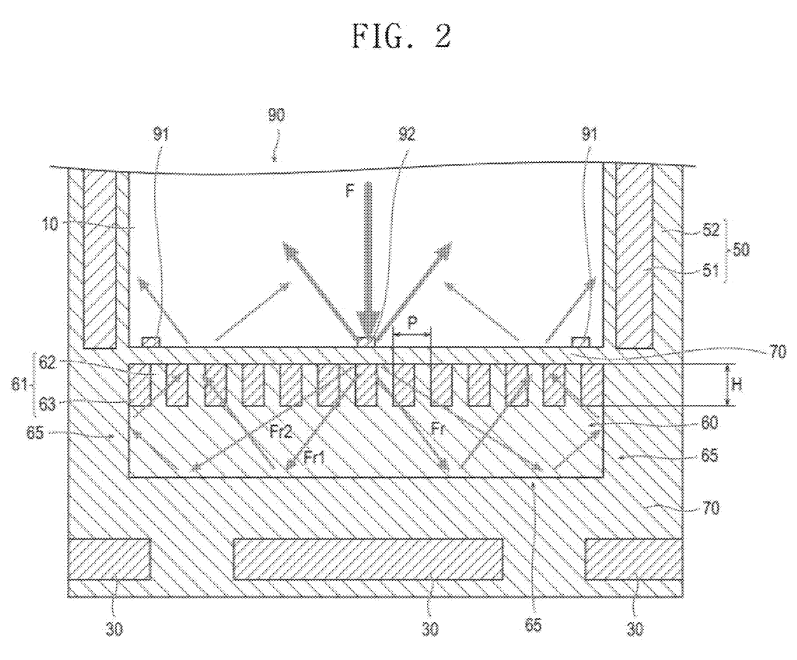

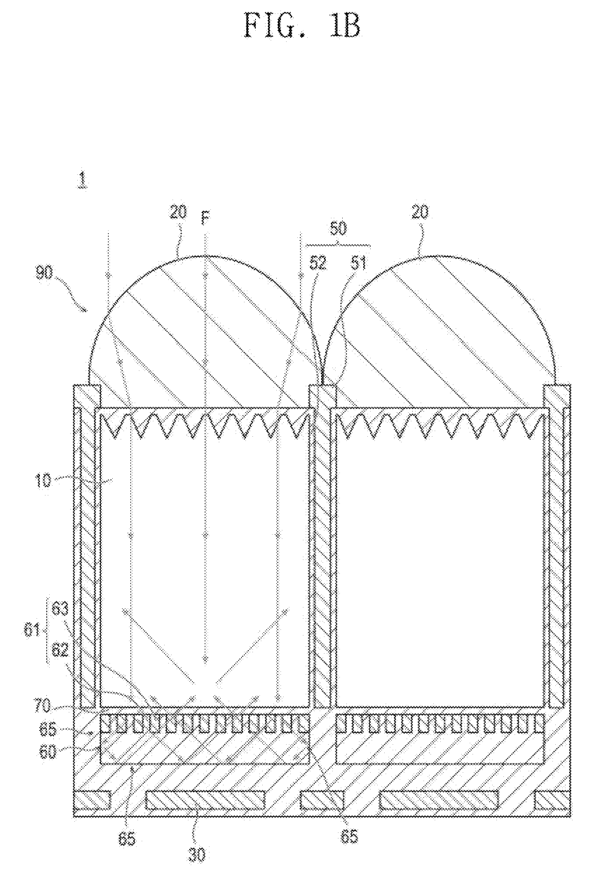

Hereinafter, an example embodiment will be described with reference to FIGS. 1a-3. It should be noted that dimensional ratios in the drawings may be exaggerated for convenience of explanation and may be different from actual ratios.

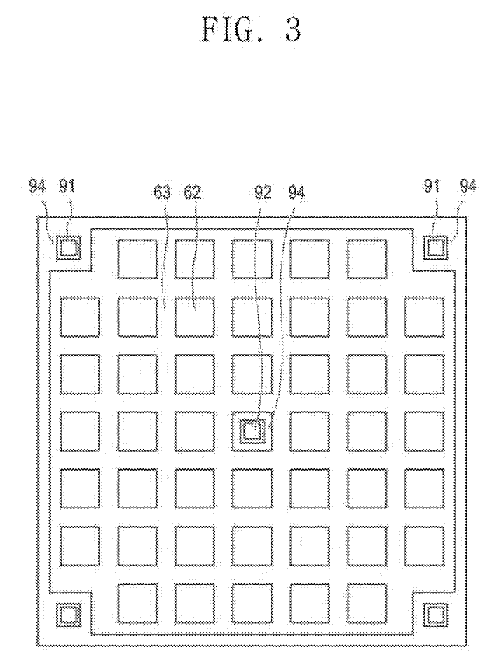

FIG. 1a is a plan view showing a pixel region composed of a plurality of pixels 90 in a solid state imaging device 1 according to an embodiment. FIG. 1b is a front cross-sectional view showing a solid state imaging device 1 according to the embodiment. FIG. 2 is a front cross-sectional view showing a part of a pixel 90 in a solid state imaging device 1 according to the embodiment. FIG. 3 is a plan view of the pixel 90 in a solid state imaging device 1 according to the embodiment .

The solid state imaging device 1 according to the embodiment may be a Complementary Metal Oxide Semiconductor (CMOS) type solid state imaging device.

It is desirable that the solid state imaging device has a high quantum efficiency (QE). QE is a ratio of the number of generated electrons to the number of incident photons.

Referring to FIG. 1a, the solid state imaging device 1 may include a pixel array in which a plurality of pixels 90 are two-dimensionally provided, for example in a matrix or array including rows and columns. Referring to FIGS. 1a, 1b, and 2, the solid state imaging device 1 may include a photoelectric conversion part such as a photodiode 10 arranged in a two-dimensional array, an on-chip lens 20 provided on an upper side of the photodiode 10, a wiring layer 30 provided on a lower side of the photodiode 10 (a side opposite to a side on which light is incident), a pixel isolation part 50 that separates a plurality of pixels 90 from each other, and a light control region 60 provided on the lower side of the photodiode 10. The photodiode 10 may be arranged in a plurality in a two-dimensional array.

Each of the pixels 90 may be a Single Photon Avalanche Diode (SPAD) pixel. The SPAD may amplify charges generated by photoelectric conversion of incident light through avalanche amplification and output them as an electrical signal. The SPAD may detect light particles one by one and has a very high time resolution. Referring to FIGS. 2, and 3, each of the pixels 90 may include an anode electrode 91 and a cathode electrode 92. An anode voltage is set to, for example, -15V to -30V, and a cathode voltage may be set to, for example, 3V. A SPAD pixel may operate in a Geiger mode as a reverse bias voltage which is equal to or higher than a breakdown voltage is applied, and may detect one photon.

photodiode 10

Referring to FIG. 1a, a plurality of photodiodes 10 may be provided in a substrate 11. For example, the substrate 11 may be a semiconductor substrate such as a silicon (Si) substrate. A lower surface of the substrate 11 is a front-side surface of the substrate 11, and an upper surface of the substrate 11 is a back-side surface of the substrate 11. Since the solid state imaging device 1 according to this embodiment is a so-called back-side illuminated type, the on-chip lens 20 may be provided on the back-side surface of the substrate 11. The back-side surface of the substrate 11 is a light incident surface of the substrate 11. The wiring layer 30 may be provided on the front-side surface of the substrate 11. A thickness of the substrate 11 may be, for example, 1 µm or more and 10 µm or less.

The photodiode 10 may be provided for each pixel 90 in the substrate 11. The photodiode 10 may include a p-type semiconductor region and an n-type semiconductor region. An avalanche multiplication region (including a pn junction of the p-type semiconductor region and the n-type semiconductor region; not shown) may be formed near the cathode electrode 92. The avalanche multiplication region avalanche-multiplies charges generated in the photodiode 10. In the photodiode 10, a potential design is made such that electrons generated by photoelectric conversion are collected in the avalanche multiplication region.

Referring to FIGS. 1b, and 2, photodiodes 10 adjacent to each other may be separated by the pixel isolation part 50, which may be an isolation pattern or structure having a metal layer 51 and a dielectric film 52. Therefore, it may be difficult for a signal charge to leak from one pixel to an adjacent other pixel. For this reason, when a signal charge exceeding a saturation charge amount is generated, leakage of the signal charge from one photodiode to an adjacent other photodiode may be reduced. Hereby, crosstalk between pixels may be suppressed.

In addition, a fixed charge film may be provided between the adjacent photodiodes 10. The fixed charge film may reduce the occurrence of dark current and may reduce noise. A material of the fixed charge film may be, for example, an oxide film or a nitride film including at least one metal element among hafnium (Hf), aluminum (Al), zirconium (Zr), tantalum (Ta), or titanium (Ti). The fixed charge film may be formed by, for example, Chemical Vapor Deposition (CVD), sputtering, or Atomic Layer Deposition (ALD).

On-chip lens 20

The on-chip lens 20 may be a microlens formed for each pixel. The on-chip lens 20 condenses incident light. The light condensed by the on-chip lens 20 is incident on the photodiode 10. In some embodiments, a light shielding film and/or a planarization film may be provided between the on-chip lens 20 and the photodiode 10.

Wiring layer 30

The wiring layer 30 takes out a signal charge generated and accumulated by the photodiode 10 as a pixel signal. The wiring layer 30 outputs the pixel signal. The number of wiring layers provided in one solid state imaging device 1, a two-dimensional arrangement, and a cross-sectional shape in a stacking direction are not particularly limited and may be variously modified.

Pixel isolation part 50

Referring to FIG. 1b, the pixel isolation part 50 may include the metal layer 51 and the dielectric film 52. As shown in FIG. 1b, the metal layer 51 may be provided between a plurality of protruding portions of a dielectric film 52. A material of the metal layer 51 may be, for example, tungsten, aluminum, or copper. A material of the dielectric film 52 may be, for example, one of silicon dioxide (SiO2), silicon nitride (SiN), aluminum oxide (AlO), tantalum oxide (TaO), titanium nitride (TiN), or titanium oxide (TiO).

Light control region 60

Next, a configuration of the light control region 60 will be described with reference to FIGS. 2, and 3. The light control region 60 is provided below the photodiode 10 with a dielectric layer 70 interposed therebetween. The dielectric layer 70 may be configured integrally with the dielectric film 52 to form an integral structure with the dielectric film 52 to have a monolithic structure formed of a continuous material without any grain boundaries therebetween. Alternatively, the dielectric layer 70 may be configured separately from the dielectric film 52, for example to have a structure formed of two pieces having a physical boundary at an interface therebetween.

Referring to FIG. 2, when viewed in a front cross-section, the dielectric layer 70 may cover the light control region 60. The light control region 60 may diffract light incident on the solid state imaging device 1 and then totally reflect it to return it to the photodiode 10, thereby greatly increasing an optical path length of the reflected light and improving QE.

The light control region 60 is provided between the photodiode 10 and the wiring layer 30. According to such a configuration, crosstalk can be reduced to decrease color mixing.

Referring to FIG. 2, the light control region 60 may include a light diffraction part 61 provided on an upper side (a side on which light is incident), and a light reflection part 65 provided on a lower side of the light diffraction part 61 and at a boundary between adjacent pixels.

Referring to FIGS. 2, and 3, the light diffraction part 61 may be a diffraction grating and may include a high-refractive-index layer 62 and a low-refractive-index layer 63. The high-refractive-index layer 62 and the low-refractive-index layer 63 may be provided periodically in two dimensions (e.g., in a two-dimensional matrix along a horizontal plane). According to an embodiment, the light diffraction part 61 may be provided adjacent to the dielectric layer 70. According to such a configuration, the light control region 60 may be easily formed.

Here, referring to FIG. 3, a method for providing the anode electrode 91, the cathode electrode 92, the high-refractive-index layer 62, and the low-refractive-index layer 63 will be described. Referring to FIG. 2, the anode electrode 91 and the cathode electrode 92 are provided below the photodiode 10 or at a bottom of the photodiode 10.

When viewed in a plan view, the cathode electrode 92 is provided in the center of the pixel 90. Further, when viewed in a plan view, the anode electrode 91 may be provided at four corners of the pixel 90. If at least one of the high-refractive-index layer 62 or the low-refractive-index layer 63 is formed of a conductive material, at least one of the anode electrode 91 and the cathode electrode 92 may be covered by an insulating layer 94. With this configuration, a short circuit may be prevented. According to this embodiment, the insulating layer 94 may be provided around the anode electrode 91 and the cathode electrode 92.

Referring to FIG. 3, in a plan view, the high-refractive-index layer 62 may be provided in a divided form as island-shaped portions (e.g., so that each island-shaped portion includes an enclosed upper surface isolated from other adjacent island-shaped portions). According to the embodiment, the high-refractive-index layer 62 may include protrusions (e.g., protruding vertically from light reflection part 65) each having a rectangular shape. The high-refractive-index layer 62 may have a refractive index, for example, greater than 1.5. Referring to FIG. 3, the low-refractive-index layer 63 may be provided in a cross shape at a position where the high-refractive-index layer 62 is not formed. The low-refractive-index layer 63 may have a refractive index, for example, less than 1.5. When used together, the high-refractive-index layer 62 has a higher refractive index than the low-refractive-index layer 63. Since the high-refractive-index layer 62 is formed to have portions discontinuous with each other, if the high-refractive-index layer 62 is an insulating material, a short circuit may be prevented even when the insulating layer 94 is not provided around the anode electrode 91 and the cathode electrode 92.

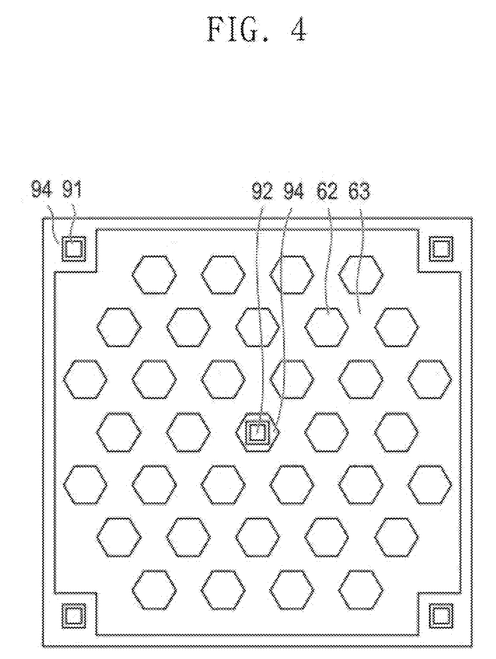

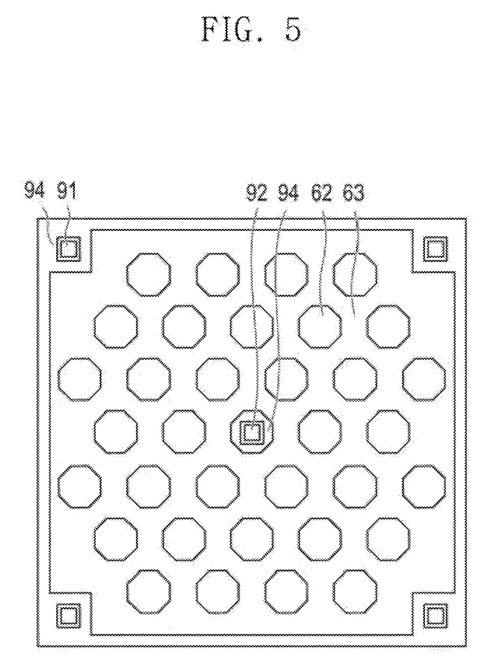

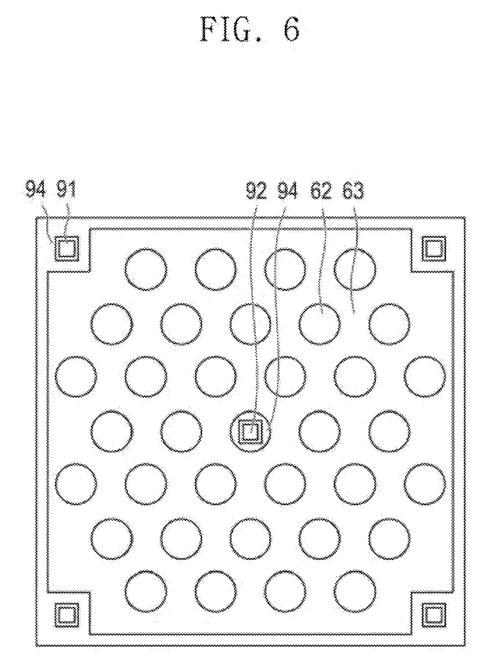

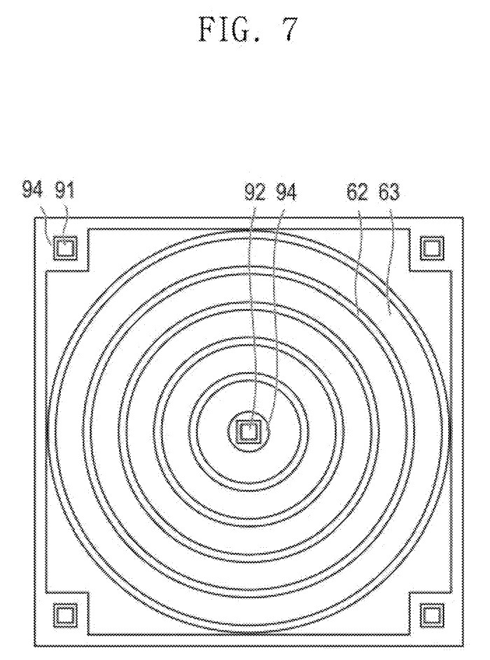

The high-refractive-index layer 62 may be a hexagon (Modification 1) with reference to FIG. 4, an octagon (Modification 2) with reference to FIG. 5, or a circle (Modification 3) with reference to FIG. 6. Furthermore, the high-refractive-index layer 62 may be a ring shape (Modification 4) with reference to FIG. 7, or a line shape (Modification 5) with reference to FIG. 8. In any configuration, in some embodiments, an area where the high-refractive-index layer 62 is provided and an area where the low-refractive-index layer 63 is provided are substantially the same. For example, from a plan view, the total area occupied by the components that form the high-refractive-index layer 62 (e.g., as can be measured from their top surfaces) may be substantially the same as the total area occupied by the components that form the low-refractive-index layer 63 (e.g., as can be measured from their top surfaces). In some embodiments, the areas can be within 10% of each other.

A material of the high-refractive-index layer 62 may be polysilicon, TiO, or SiN. However, it is not particularly limited thereto. A material of the low-refractive-index layer 63 may be air (Air Gap structure) or silicon oxide (SiO). However, it is not particularly limited thereto. It should be appreciated that “air” or an “air gap” may comprise a component having air or other gases (e.g., such as those present during manufacturing) or may comprise a gap forming a vacuum therein.

The light reflection part 65 is configured by the high-refractive-index layer 62 and the dielectric layer 70, and may include a portion of the light control region 60 below the light diffraction part 61 that forms a well through which light passes and is reflected at internal surfaces thereof. The dielectric layer 70 has a smaller refractive index than the high-refractive-index layer 62.

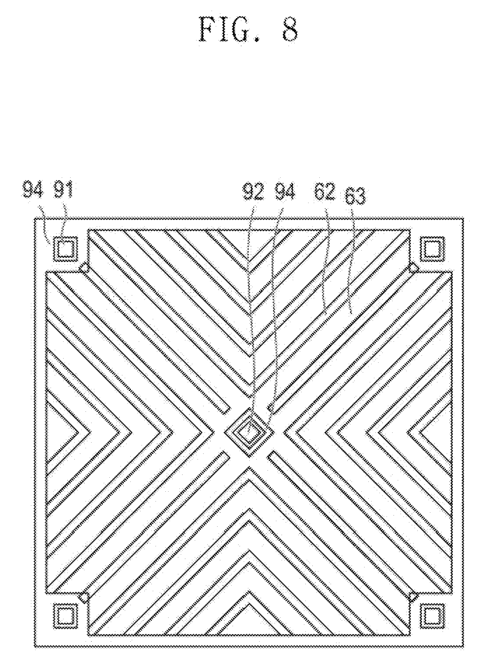

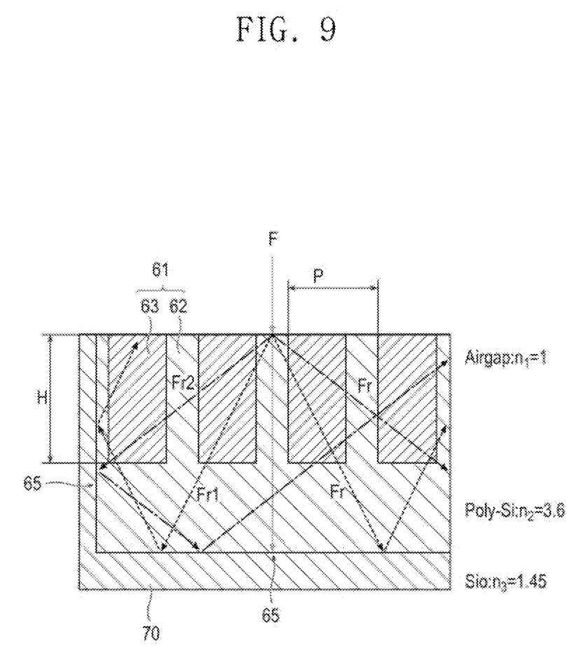

Referring to FIGS. 2, and 9, an operation effect of the light diffraction part 61 (improvement of quantum efficiency by diffracted light) will be described. FIGS. 2, and 9 are schematic diagrams for explaining a generation principle of diffracted light.

The high-refractive-index layer 62 and the low-refractive-index layer 63 of the light diffraction part 61 may be provided with a two-dimensional periodic (P) regularity. Referring to FIGS. 2, and 9, incident light F is incident on the light control region 60 from an upper side of the photodiode 10. The light diffraction part 61 of the light control region 60 generates diffracted light Fr. Since the light diffraction part 61 has a two-dimensional period P, the light diffraction part 61 may generate diffracted light Fr in parts according to the two-dimensional period P.

Referring to FIGS. 2, and 9, the diffracted light Fr generated by the light diffraction part 61 does not travel along the shortest straight line distance from the upper side to the lower side of the light control region 60, but travels in an oblique direction within the light control region 60. Since this light in the oblique direction returns to the photodiode 10, for example due to total internal reflection, the pixel 90 may increase an optical path length of light that the photodiode 10 converts into charges, as compared with a case where the diffracted light Fr is not generated. As the optical path length of light that the photodiode 10 converts into charges increases, a light absorption amount in the photodiode 10 increases. Hereby, the pixel 90 may have a high QE.

A period P of the light diffraction part 61 is configured to have a predetermined length based on a wavelength of light received by the light diffraction part 61(same as a wavelength of the incident light) and an incident angle of light received by the light diffraction part 61. In addition, the period P of the light diffraction part 61 may be shorter than the wavelength of the received light, and may be provided with a length that can generate diffracted light Fr in the light control region 60.

FIG. 9 illustrates first-order diffracted light Fr1 and second-order diffracted light Fr2 generated from the light received by the light diffraction part 61. By setting the period P to an appropriate length according to an incident angle and the wavelength of the incident light F, the pixel 90 may generate the first-order diffracted light Fr1 and the second-order diffracted light Fr2 in the light control region 60.

For example, when an incident angle of the incident light F is 0° and the wavelength of the incident light F is 940 nm, in one embodiment, a length of the period P (see FIG. 2) is 400 nm to 600 nm, and may be more specifically 600 nm. Here, when a refractive index of the low-refractive-index layer 63 is n₁ (n1=1 in case of Air Gap), m is a natural number, λ is a wavelength of the incident light, a refractive index of the high-refractive-index layer 62 is n₂ (n₂=3.6 in case of polysilicon), and a diffraction angle is θ, an equation for transmitted diffracted light can be expressed as n₁×sin0°±mλ/P=n₂×sinθ. When the period P is 600 nm, from the equation for transmitted diffracted light, a diffraction angle θ1 (m=1) between the incident light F and the first-order diffracted light Fr1 is, for example, 26.6°, and a diffraction angle θ2 (m=2) between the incident light F and the second-order diffracted light Fr2 is, for example, 63.5°.

In addition, when a refractive index of the dielectric layer 70 is n₃ (n₃=1.45 in case of SiO₂) and an incident angle at the time of total reflection is θ', an equation for a total reflection condition may be n₂sinθ'=n₃sin90°. Therefore, a total reflection condition in the light reflection part 65 may be calculated to be 23.7° or more. For this reason, the diffracted light Fr satisfies the total reflection condition and is totally reflected at the light reflection part 65 to be absorbed by the photodiode 10. As such, by providing the light reflection part 65, the incident light does not move to an adjacent pixel, so crosstalk may be suppressed and color mixing may be suppressed.

The length of the period P is not particularly limited as long as it can generate the diffracted light Fr in the light control region 60 in consideration of the incident angle and the wavelength of the incident light F. For example, even if the incident angle of the incident light F is not 0° or the wavelength of the incident light F is not 940 nm, the period P may be changed to have an appropriate length based on the equation for transmitted diffracted light.

A height H of the light diffraction part 61 is preferably smaller than the wavelength of the incident light. Here, the height of the light diffraction part 61 is a length in a stacking direction (e.g., the vertical direction) of the light diffraction part 61. According to such a configuration, an increase in size of the solid state imaging device 1 may be suppressed.

In the solid state imaging device according to aspects of this disclosure, since a light control region is formed outside a photodiode, it is not necessary to etch Si constituting the photodiode. In addition, since the light control region includes a light diffraction part, an optical path length is increased to improve QE. Therefore, it is possible to improve QE while suppressing the deterioration of dark current.

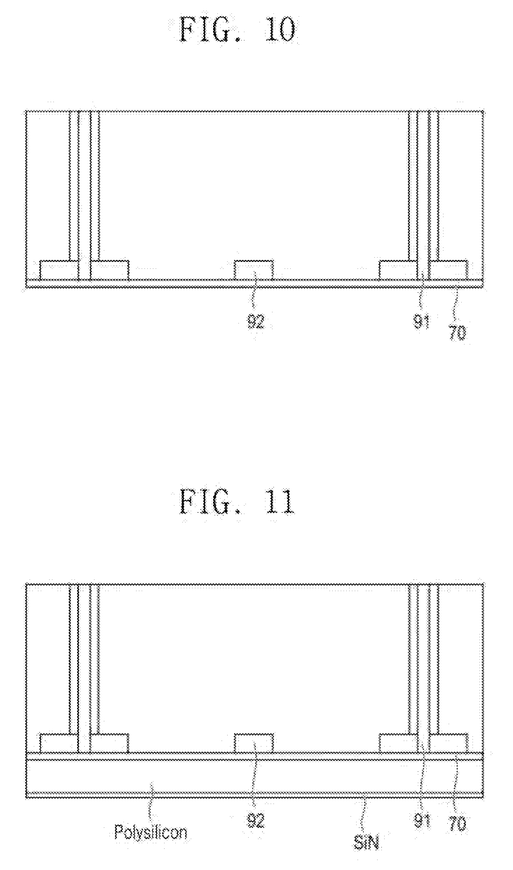

Next, a manufacturing method of the solid state imaging device 1 according to an embodiment will be described with reference to FIGS. 10 to 21. Here, a case where the high-refractive-index layer 62 is polysilicon and the low-refractive-index layer 63 is air (Air Gap) will be described as an example.

First, referring to FIG. 10, the SPAD pixel is formed. Since a method for forming the SPAD pixel is known, a detailed description thereof will be omitted.

Next, referring to FIG. 11, polysilicon is formed below SiO (dielectric layer 70), and SiN used as a mask is formed below the polysilicon.

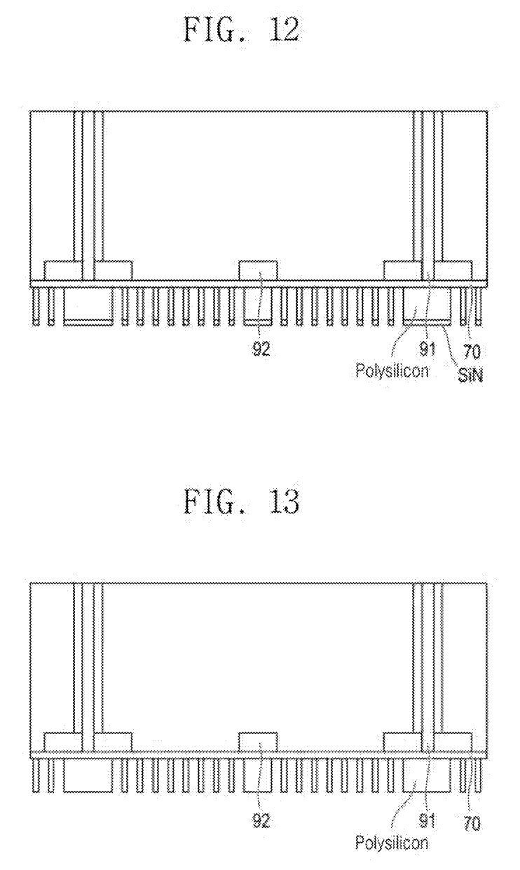

Next, referring to FIG. 12, the polysilicon is etched using a SiN pattern of the period P as a mask. Then, referring to FIG. 13, the SiN pattern is etched and completely removed.

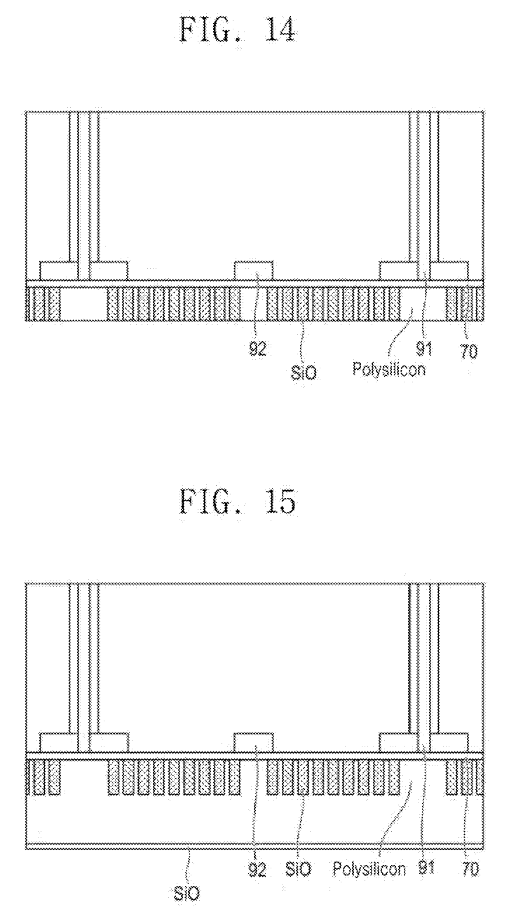

Next, referring to FIG. 14, a SiO sacrificial layer is formed in a space where the polysilicon was etched.

Next, referring to FIG. 15, polysilicon and SiO are formed below the polysilicon and the SiO sacrificial layer.

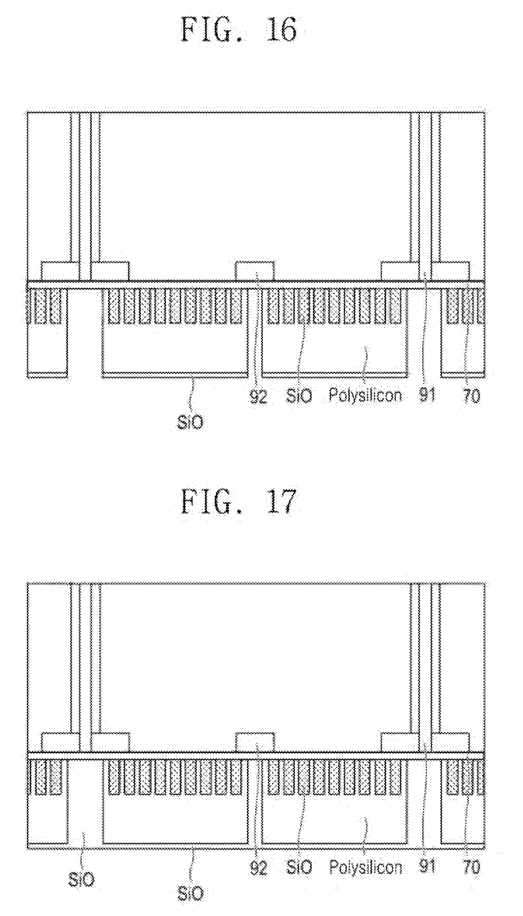

Next, referring to FIG. 16, SiO and polysilicon are etched for wiring formation.

Next, referring to FIG. 17, SiO is formed in a space etched in a previous process. This SiO functions as the light reflection part 65 or the insulating layer 94.

Next, referring to FIG. 18, after dry-etching SiO and polysilicon on a rear side with a small diameter, the SiO sacrificial layer is removed by wet etching to form a hollow structure for the low-refractive-index layer 63. Here, only the SiO sacrificial layer is wet-etched so that excessive etching does not occur.

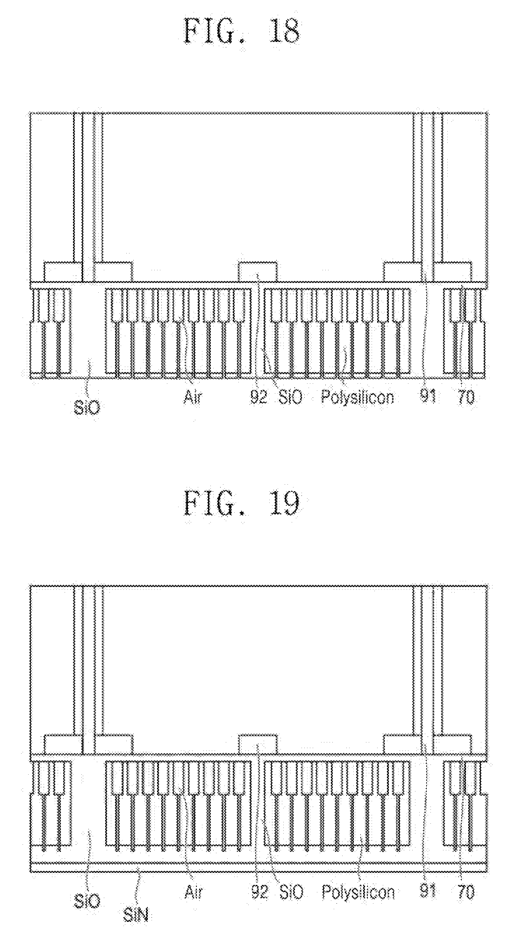

Next, referring to FIG. 19, SiO and SiN are formed to fill a through-hole etched in the previous process. Here, SiN functions as a mask.

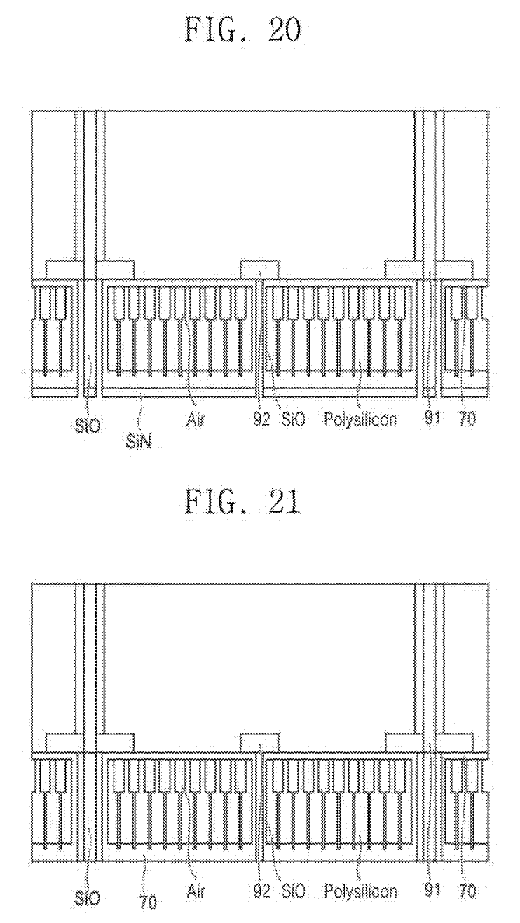

Next, referring to FIG. 20, SiN and SiO are etched to form a connection wiring for the anode electrode 91 and the cathode electrode 92. Referring to FIG. 21, the connection wiring is formed in the etched space and connected to each electrode. Through the above processes, the solid state imaging device 1 according to an embodiment is manufactured. In addition, when SiO is used as the low-refractive-index layer 63, the SiO sacrificial layer formed in FIG. 14 may be used as the low-refractive-index layer.

Based on the above embodiments, a solid state imaging device may include a pixel array in which a plurality of pixels are two-dimensionally arranged. Each of the pixels may include a microlens such as on-chip lens 20 and a photodiode 10 having a first surface facing the microlens and a second surface opposite the first surface. The photodiode is configured to receive light from the microlens at the top surface. Each of the pixels may further include a dielectric layer 70 below the photodiode, and a light control region 60 in the dielectric layer 70. The light control region 60 may include a diffraction grating (e.g., 61) that includes a matrix of first refractive-index material surrounded by a layer of a second refractive-index component. The first refractive-index material may have a higher refractive index than the second refractive-index component.

The light control region 60 may further include a reflection region such as light reflection part 65 below the diffraction grating and formed of the first refractive-index material. The matrix of first refractive-index material may include protrusions protruding from the reflection region. The first refractive-index material may be polysilicon, TiO, or SiN, and the second refractive-index component may be formed of SiO or air. The dielectric layer 70 may be formed between the photodiode 10 and the light control region 60. The solid state imaging device may further include a metal film 51 formed between pixels of the pixel array to additionally reflect light.

Based on the above embodiments, a pixel array may include a plurality of pixels two-dimensionally arranged. Each of the pixels comprises a photodiode 10, a dielectric layer 70, a light diffraction grating, and a reflection region below the diffraction grating. The photodiode may have a top side upon which light is incident to the photodiode and a bottom side opposite the top side, and the dielectric layer 70 may be provided on the bottom side. In addition, the pixel array includes a light diffraction grating provided below the dielectric layer and configured to receive light having passed through the photodiode. The light diffraction grating may include two patterns alternately arranged, such as, for example, high-refractive-index layer 62, and low-refractive-index layer 63. A light reflection region (e.g., light reflection part 65) may be disposed below the light diffraction grating, and may be configured to reflect refracted light that has passed through the diffraction grating back to the photodiode 10.

The two patterns include a first pattern formed of a first component having a first refractive index, and a second pattern formed of a second component having a second refractive index lower than the first refractive index. In addition, the first component may be a polysilicon, nitride, or oxide, and the second component may be an oxide or air

This disclosure is not limited to the above-described embodiments, but may be variously modified. For example, according to the above-described embodiments, the light control region 60 has the light reflection part 65, but it may not have this. In addition, according to the above-described embodiment, the light control region 60 is formed between the photodiode 10 and the wiring layer 30, but the light control region 60 may be formed below the wiring layer 30.

In addition, according to the above-described embodiments, the pixel 90 is the SPAD pixel, but it may not be the SPAD pixel and may be a different type of pixel. In addition, according to the above-described embodiment, the anode electrode 91 and the cathode electrode 92 are covered by the insulating layer 94, but they may not be.

What is claimed is:

1. A solid state imaging device comprising a pixel array in which a plurality of pixels are two-dimensionally arranged,
wherein each pixel of the plurality of pixels comprises:
a photodiode having a first side upon which light is incident to the photodiode and a second side opposite the first side;
a dielectric layer provided on the second side; and
a light control region provided on the second side and disposed in the dielectric layer so that at least part of the dielectric layer is between the photodiode and the light control region,
wherein the light control region has a light diffraction grating in which a high-refractive-index layer and a low-refractive-index layer are periodically arranged.

2. The solid state imaging device of claim 1,
wherein the light diffraction grating has a first side facing the photodiode and a second side facing away from the photodiode, and
wherein the light control region has a light reflection region that is provided on the second side of the light diffraction grating and at a boundary between adjacent pixels and that reflects the light.

3. The solid state imaging device of claim 2, wherein a period of the light diffraction grating is set such that the light is totally reflected at the light reflection region.

4. The solid state imaging device of claim 1, wherein the light diffraction grating is provided adjacent to the dielectric layer.

5. The solid state imaging device of claim 1, wherein each of the pixels further includes a wiring layer provided on the second side of the photodiode, and the light control region is formed between the photodiode and the wiring layer.

6. The solid state imaging device of claim 1,
wherein each pixel of the plurality of pixels is a Single Photon Avalanche Diode (SPAD) pixel,
wherein each pixel of the plurality of pixels further includes an anode electrode and a cathode electrode,
wherein for each pixel, when viewed in a plan view, the cathode electrode is provided in a center of the pixel, and the anode electrode is provided at four corners of the pixel.

7. The solid state imaging device of claim 6, wherein:
when at least one of the high-refractive-index layer or the low-refractive-index layer is formed of a conductive material, at least one of the anode electrode or the cathode electrode is covered by an insulating layer.

8. The solid state imaging device of claim 1, wherein the high-refractive-index layer is one of an island shape, a ring shape, or a line shape.

9. The solid state imaging device of claim 1, wherein a height of the light diffraction grating is smaller than a wavelength of the light.

10. The solid state imaging device of claim 1, wherein the low-refractive-index layer is one of a hollow structure or SiO.

11. The solid state imaging device of claim 10, wherein the high-refractive-index layer is one of polysilicon, TiO, or SiN.

12. The solid state imaging device of claim 1, further comprising a microlens.

13. A solid state imaging device, comprising a pixel array in which a plurality of pixels are two-dimensionally arranged,
wherein each of the pixels comprises:
a microlens;
a photodiode having a first surface facing the microlens and a second surface opposite the first surface, the photodiode configured to receive light from the microlens at the first surface;
a dielectric layer below the photodiode; and
a light control region in the dielectric layer, wherein:
the light control region includes a diffraction grating that includes a matrix of first refractive-index material surrounded by a layer of a second refractive-index component, the first refractive-index material having a higher refractive index than the second refractive-index component.

14. The solid state imaging device of claim 13, wherein:
the light control region further includes a reflection region below the diffraction grating and formed of the first refractive-index material.

15. The solid state imaging device of claim 14, wherein the matrix of first refractive-index material includes protrusions protruding from the reflection region.

16. The solid state imaging device of claim 13, wherein the first refractive-index material is polysilicon, TiO, or SiN, and the second refractive-index component is formed of SiO or air.

17. The solid state imaging device of claim 13, wherein the dielectric layer is between the photodiode and the light control region.

18. The solid state imaging device of claim 13, further comprising:
a metal film formed between pixels of the pixel array to additionally reflect light.

19. A pixel array in which a plurality of pixels are two-dimensionally arranged,
wherein each of the pixels comprises:
a photodiode having a top side upon which light is incident to the photodiode and a bottom side opposite the top side;
a dielectric layer provided on the bottom side;
a light diffraction grating provided below the dielectric layer and configured to receive light having passed through the photodiode, the light diffraction grating including two patterns alternately arranged; and
a reflection region below the light diffraction grating and configured to reflect refracted light that has passed through the light diffraction grating back to the photodiode.

20. The pixel array of claim 19, wherein the two patterns include a first pattern formed of a first component having a first refractive index, and a second pattern formed of a second component having a second refractive index lower than the first refractive index, the first component is a polysilicon, nitride, or oxide, and the second component is an oxide or air.
